(19) United States
(12) Patent Application Publication
(10) Pub. No.: US 2009/0140418 A1
(43) Pub. Date: Jun. 4, 2009

(54) METHOD FOR INTEGRATING POROUS LOW-K DIELECTRIC LAYERS

(76) Inventors: SIYI LI, Fremont, CA (US); Li-Qun Xia, Cupertino, CA (US); Michael D. Armacost, San Jose, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/947,638

(22) Filed: Nov. 29, 2007

(51) Int. Cl. H01L 21/311; H01L 23/48

(52) U.S. Cl. 257/734; 438/694; 257/E23.01; 257/E21.24

(57) ABSTRACT

Described herein are methods for integrating low-k dielectric layers with various interconnect structures. In one embodiment, a method for restoring a porous dielectric layer includes forming an opening in the porous low-k dielectric layer. The method further includes forming an opening in a barrier layer. The method further includes depositing a restoring dielectric layer to seal a surface layer of pores of the porous dielectric layer. In one embodiment, the restoring dielectric layer is non-porous and hydrophobic to prevent the porous dielectric layer from adsorbing moisture and consequently increasing the dielectric constant of the porous dielectric layer. The method further includes performing a clean operation on the interconnect structure prior to metallization. The method further includes depositing, masking, and etching a metal layer.

### TECHNICAL FIELD

Embodiments of the present invention relate to integrating porous low dielectric constant (k) layers, and more specifically to restoring porous low-k layers.

### BACKGROUND

As semiconductor manufacturing technology advances to smaller and smaller feature sizes, porous low-k integration with Copper interconnect technology has been widely evaluated. Interconnect delay becomes a significant performance barrier for high-speed signal conduction. The use of dielectric materials with a lower dielectric constant (k) can significantly improve performance measures by reducing signal propagation time delay, cross talk, and power consumption in semiconductor devices having a multilevel interconnect architecture. The most-used dielectric material for semiconductor fabrication has been silicon oxide (SiO₂), which has a dielectric constant in the range of k=3.9 to 4.5, depending on its method of formation. Dielectric materials with k less than 3.9 are classified as low-k dielectrics. Some low-k dielectrics are organosilicates formed by doping silicon oxide with carbon-containing compounds.

Integration of porous low-k layers has exerted significant challenges. First, a barrier metal (e.g., Tantalum Nitride, Tantalum) or even Copper penetration into the dielectric results in increased leakage and capacitance. Second, plasma processing during various well-known etching and/or stripping operations causes damage to porous low-k dielectric layers.

The steps of etching the dielectric material and removing a masking layer may be performed with an O₂-containing plasma, which can degrade the dielectric properties of the dielectric material through oxidation. This damage to the material is believed to occur when Silicon (Si)—Carbon (C) bonds, methyl groups, are broken and hydrophilic hydroxyl (OH) groups replace the hydrophobic methyl groups. The polarity of the dielectric material is thus changed and the damaged dielectric more easily absorbs moisture, resulting in an increase of both leakage current and dielectric constant. Subsequent heating of the damaged dielectric material can release moisture, interfering with the process of filling the etched cavities with metal. Semiconductor devices fabricated with such damaged dielectric material exhibit reduced performance measures and increased fabrication defects compared to devices fabricated with undamaged dielectric material.

Prior approaches for restoring the damaged dielectric material include treatment with hydrocarbon, fluorocarbon, or organo-substituted silane gases (e.g., (CH₃)ₓSiH₄₋ₓ, where x is 1 to 4). This treatment has been shown to reduce defects in metal fillings deposited on the treated dielectric material. However, the effect of this treatment on the dielectric properties of the damaged dielectric material has not been demonstrated. As a result, the damaged and/or modified low-k surface becomes hydrophilic which will increase moisture absorption during the following wafer processing and consequently leads to an increase in the effective dielectric constant of the integrated structure.

For semiconductor manufacturing technology, feature critical dimension (CD) is critical for device performance. The CD control includes mask (lithographic) CD and final CD after pattern transfer during an etch operation. As the technology advances towards 45 nanometers (nm) and beyond, feature CD control, particularly to print the features with a small CD, becomes a major concern because the existing lithographic tools are approaching the tool limits and it becomes extremely expensive for more advanced tools.

A prior approach to reduce feature CDs includes etch-assisted CD control. The CD is reduced by forming polymer in the space or contact/via before plasma etching. However, the process window needs to be widened for issues like etch stop in an open area, formation of striation, line edge roughness, CD shrinking uniformity between small and large features, and particle addition.

### BRIEF DESCRIPTION OF THE DRAWINGS

The present invention is illustrated by way of example, and not by way of limitation, in the figures of the accompanying drawings and in which:

FIG. 1 illustrates one embodiment of a method for integrating a low-k dielectric layer into an interconnect structure;

FIG. 2A illustrates a cross-sectional view of an interconnect structure in accordance with one embodiment;

FIG. 2B illustrates a cross-sectional view of an interconnect structure in accordance with another embodiment;

FIG. 3A illustrates a cross-sectional view of an interconnect structure in accordance with another embodiment;

FIG. 3B illustrates a cross-sectional view of an interconnect structure in accordance with another embodiment;

FIG. 4 illustrates one embodiment of a method for reducing a critical dimension of an interconnect structure by integrating a low-k dielectric layer into the interconnect structure;

FIG. 5A illustrates a cross-sectional view of an interconnect structure in accordance with one embodiment;

FIG. 5B illustrates a cross-sectional view of an interconnect structure in accordance with another embodiment;

FIG. 6A illustrates a cross-sectional view of an interconnect structure in accordance with another embodiment; and

FIG. 6B illustrates a cross-sectional view of an interconnect structure in accordance with another embodiment.

### DETAILED DESCRIPTION

Described herein are methods for integrating low-k dielectric layers with various interconnect structures. In one embodiment, a method for restoring a porous dielectric layer includes forming an opening in the porous low-k dielectric layer. The method further includes forming an opening in a barrier layer. The method further includes depositing a restoring dielectric layer to seal a surface layer of pores of the porous dielectric layer. In one embodiment, the restoring dielectric layer is non-porous and hydrophobic to prevent the porous dielectric layer from adsorbing moisture and consequently increasing the dielectric constant of the porous dielectric layer. The method further includes performing a clean operation on the interconnect structure prior to metallization. The method further includes depositing, masking, and etching a metal layer.

In another embodiment, the restoring dielectric layer is a low-k material being integrated into a dual-damascene process. The restoring dielectric layer prevents metal diffusion into the porous low-k dielectric layer and moisture adsorption during subsequent processing. Additionally, the restoring dielectric layer has a dielectric constant similar to the porous low-k dielectric layer resulting in nearly no increase in the dielectric constant of the combination of the layers. The restoring dielectric layer can advantageously be formed before, after, or before and after a barrier open operation.

In some embodiments, a method for reducing a critical dimension of a interconnect structure by integrating a low-k dielectric layer into an interconnect structure is described. The method of controllably reducing at least one opening in interconnect structure includes forming the at least one opening (e.g., via, trench) in a first dielectric layer. The method further includes depositing a second dielectric layer. The method further includes etching the second dielectric layer with a first anisotropic etch to controllably reduce a CD of the at least one opening in the interconnect structure. The first anisotropic etch etches at a faster rate on horizontal surfaces compared to vertical surfaces. The method further includes depositing a third dielectric layer. The method further includes etching the third dielectric layer with a second anisotropic etch. Depositing and etching the third dielectric layer occurs in order to further controllably reduce the CD of the at least one opening in the interconnect structure.

The method for controllably reducing the CD extends the use of conventional lithographic tools as opposed to having to invest in next generation tools which are extremely expensive. Depositing and etching back the various dielectric layers results in no striations, line edge roughness, or etch stop issues as caused during etch-assisted CD reduction. The CD can be finely tuned as the deposition process is combined with the plasma etching process, possibly in the same process chamber. The low-k dielectric layer as-deposited is hydrophobic and will not absorb moisture during subsequent processing.

The following description provides details of manufacturing machines that process substrates and/or wafers to manufacture devices (e.g., electronic devices, semiconductors, substrates, liquid crystal displays, reticles). Manufacturing such devices generally requires dozens of manufacturing steps involving different types of manufacturing processes. For example, etching, sputtering, and chemical vapor deposition are three different types of processes, each of which is performed on different chambers or in the same chamber of a machine.

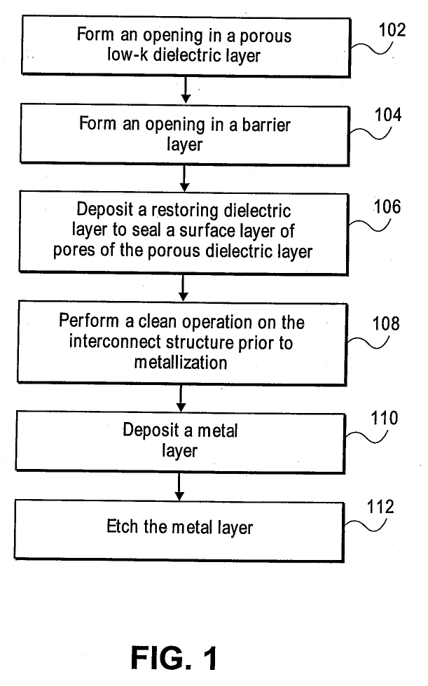

FIG. 1 illustrates one embodiment of a method for integrating a porous low-k dielectric layer into an interconnect structure. The method includes forming an opening in the porous low-k dielectric layer having a density and pores of a certain size (e.g., 5 to 20 Angstroms) at block 102. For example, the porous low-k dielectric layer can be a pyrogenic film, a carbon doped oxide, a black diamond film, or other type of dielectric layer having a low or ultra low k. The opening can be formed in a number of conventional semiconductor processing operations such as using a plasma etching operation to etch the dielectric layer and a plasma ashing operation to remove a masking layer (e.g., photoresist). The plasma etching and/or ashing operations damage and/or modify the dielectric layer. This damage to the dielectric layer occurs when Si—C bonds are broken and hydrophilic hydroxyl (OH) groups replace the hydrophobic methyl groups. The polarity of the dielectric material is thus changed and the damaged dielectric more easily absorbs moisture, resulting in an increase of both leakage current and dielectric constant as the dielectric constant depends on the amount of Carbon (C) in the film.

In one embodiment, a plasma ashing operation has a pressure of approximately 10 millitorr (mT) with a plasma gas chemistry of less than 500 cubic centimeters per minute (sccm) of oxygen or carbon dioxide and a radio frequency (rf) power less than 500 watts (W). Other process parameters for the plasma ashing operation and other standard semiconductor processing operations may damage and/or modify the dielectric layer such as plasma etching and chemical mechanical planarization.

The method further includes forming an opening in a barrier layer at block 104. The barrier layer (e.g., Ta, TaN, silicides) is part of the interconnect structure that prevents previously and/or subsequently deposited metal layers (e.g., aluminum, aluminum copper, copper) from diffusing into other processing layers. The method further includes depositing a restoring dielectric layer to seal a surface layer of pores of the porous dielectric layer at block 106. In one embodiment, the restoring dielectric layer is non-porous and hydrophobic to prevent the porous dielectric layer from adsorbing moisture and consequently increasing the dielectric constant of the porous dielectric layer. The method further includes performing a clean operation on the interconnect structure prior to metallization at block 108. The method further includes depositing a metal layer at block 110. This deposition may include depositing a liner layer prior to depositing or plating the metal layer onto the interconnect structure. The method further includes etching the metal layer at block 112.

In one embodiment, the metal layer is etched with a chemical-mechanical planarization or chemical-mechanical polishing (CMP) process. This process is used in semiconductor fabrication for planarizing the top surface of an in-process semiconductor wafer or other substrate. In another embodiment, other conventional semiconductor processing occurs in order to etch the metal layer such as a blanket unmasked plasma etch or a masked plasma etch or a combination of conventional semiconductor processing.

In one embodiment, the restoring dielectric layer has a thickness with a range of 5 to 30 Angstroms. In another embodiment, the restoring dielectric layer has a thickness with a range of 5 to 20 Angstroms. The thickness of the restoring dielectric layer is optimized for a particular application. For example, if the thickness of the restoring dielectric layer is too thin, the surface of the porous dielectric layer that is hydrophilic will not convert into a non-porous, hydrophobic surface. Alternatively, if the thickness of the restoring dielectric layer is too thick, then subsequently deposited metal layers may have adhesion issues.

In one embodiment, a pre-anneal operation occurs prior to the deposition of the restoring dielectric layer. The pre-anneal operation removes moisture from the damaged dielectric layer among other layers on a wafer and/or substrate. For example, a pre-anneal operation may occur at 350 degrees Celsius (C) at 6 torr with 5000 sccm of Argon gas for a certain time period.

For some embodiments, the deposition of the restoring dielectric layer occurs with a deposition operation (e.g., chemical vapor deposition, physical chemical vapor deposition, plasma enhanced chemical vapor deposition) that includes an organosilicate precursor (e.g., octa-methyl-cyclo-tetra-siloxane (OMCTS), tetra-methyl-cyclo-tetra-siloxane (TMCTS), tri-methyl-silane (TMS), tetra-ethyl-ortho-silicate (TEOS), and di-ethoxy-methyl-silane (DEMS)) that has a composition of SiₓC_{y}O_{z}Hₘ with x=1-5, y=1-15, z=0-10, and m=3-45. In one embodiment for a particular chamber size, the RF power is less than or equal to 75 W for a power density of 0.66 watt per square inch of wafer size with a precursor/Helium ratio greater than or equal to 1:4. A spacing between electrodes (e.g., heater and faceplate) is greater than or equal to 200 mils with one mil equaling one-thousandth of an inch. The pressure during the deposition is greater than or equal to 1.8 torr with a chamber temperature between 0 and 500° C.

The deposition is self-limiting to form a thin uniform conformal Carbon doped oxide layer. Continuous growth can be enabled with a Carbon removal operation using an O₂, CO₂, or N₂O plasma diluted in N₂, Argon or Helium. A final film thickness can be achieved by using a cyclic deposition. The Carbon content on the surface of the restoring dielectric layer can be adjusted to make the surface hydrophobic or hydrophilic. The Carbon to Silicon ratio is typically between 1:1 and 2:1 with a higher concentration of Carbon resulting in a hydrophobic surface.

In some embodiments, the porous and restoring dielectric layers each have low (k<3.9) or ultra (k<2.5) dielectric constants. The porous and restoring dielectric layers can be the same or similar materials. However, the restoring dielectric layer is a very thin film to ensure that this film is non-porous and hydrophobic. The restoring dielectric layer contains Si—CH₃ (methyl groups) that determine the porosity and density of the layer. This layer is grown at a slow rate in a controllable manner to produce a dense, high quality film without pores that prevents an increase in the dielectric constant of the combination of the restoring layer and the porous layer. This layer also functions to prevent an increase in leakage current and capacitance of the porous layer by preventing moisture and impurities from diffusing into the porous layer. Thus, the restoring layer improves reliability and performance of the interconnect structure and/or devices being formed by the semiconductor processing.

The operations of methods described in the present invention can be performed in a different order, sequence, and/or have more or less operations than described. For example, in one embodiment, the deposition of the restoring dielectric occurs prior to forming an opening in a barrier layer at block 104. In another embodiment, the deposition of the restoring dielectric occurs prior to and after forming an opening in a barrier layer at block 104.

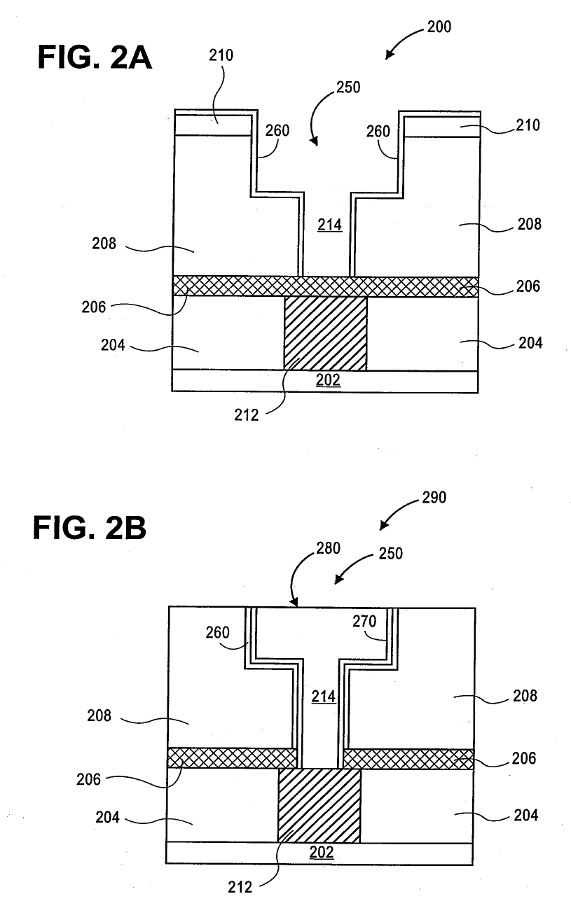

FIG. 2A illustrates a cross-sectional view of an interconnect structure in accordance with one embodiment. The interconnect structure 200 includes a substrate 202, a dielectric layer 204, a metal layer 212, a barrier layer 206, a porous low-k dielectric layer 208, and a masking layer 210 (e.g., Silicon Nitride). In one embodiment, the interconnect structure 200 is a dual-damascene structure having at least one via 214 and at least one trench 250 formed from conventional semiconductor deposition, lithography, etch, strip, and planarization operations. Dual-damascene forms studs and interconnects with one planarization operation. The dual-damascene process increases the density, performance, and reliability in a fully integrated wiring technology.

After the via 214 and the trench 250 have been formed and an optional masking layer (not shown) removed, the porous dielectric layer 208 will be damaged or modified from the plasma etching and/or plasma ashing operations. In one embodiment, a thin restoring dielectric layer 260 is deposited on the interconnect structure 200 to seal a surface layer of pores of the porous dielectric layer 208. The restoring dielectric layer 260 is hydrophobic to prevent the porous dielectric layer 208 from adsorbing moisture and consequently increasing a dielectric constant of the porous dielectric layer 208.

FIG. 2B illustrates a cross-sectional view of an interconnect structure in accordance with another embodiment. The interconnect structure 290 of FIG. 2B further includes a metal liner layer 270 and a metal layer 280 in comparison to the interconnect structure 200 of FIG. 2A. In one embodiment, a chemical-mechanical planarization process etches a top surface of the interconnect structure 290. The metal layer 280, liner 270, dielectric layer 260, and masking layer 210 are etched until reaching the porous dielectric layer 208 resulting in the interconnect structure 290. The masking layer 210 having a higher dielectric constant in comparison to the porous dielectric layer 208 may be completely removed in order to minimize the dielectric constant of the interconnect structure 290. In some embodiments, the planarization process stops etching upon reaching the masking layer 210 thus leaving a portion of the masking layer 210. The at least one via 214 and at least one trench 250 have been filled with the metal layer 280 (e.g., Cu plating, AlCu deposition).

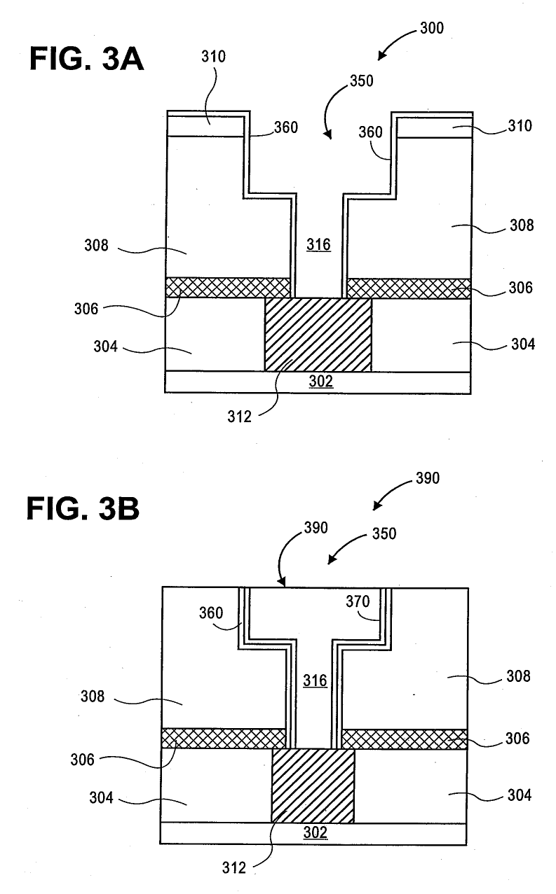

FIG. 3A illustrates a cross-sectional view of an interconnect structure in accordance with another embodiment. The interconnect structure 300 includes a substrate 302, a dielectric layer 304, a metal layer 312, a barrier layer 306, a porous low-k dielectric layer 308, and a masking layer 310 (e.g., Silicon Nitride). In one embodiment, the interconnect structure 300 is a dual damascene structure having at least one via 316 and at least one trench 350 formed from conventional semiconductor deposition, lithography, etch, and strip operations. In another embodiment, the interconnect structure 300 is a single damascene structure or other structure that forms an opening in a porous dielectric layer.

After the via 316 and the trench 350 have been formed and a masking layer (not shown) removed, the porous dielectric layer 308 will be damaged or modified from the plasma etching and/or plasma ashing operations. In one embodiment, the porous dielectric layer 308 is disposed on the barrier layer 306 with at least one opening in the porous dielectric layer overlying at least one opening in the barrier layer. A restoring dielectric layer 360 is disposed to seal a surface layer of pores of the porous dielectric layer 308. The restoring dielectric layer 360 is hydrophobic to prevent the porous dielectric layer 308 from adsorbing moisture and consequently increasing a dielectric constant of the porous dielectric layer 308.

FIG. 3B illustrates a cross-sectional view of an interconnect structure in accordance with another embodiment. The interconnect structure 390 of FIG. 3B further includes a metal liner layer 370 (e.g., TaN, TiN) and a metal layer 380 in comparison to the interconnect structure 300 of FIG. 3A. In one embodiment, a chemical-mechanical planarization process etches a top surface of the interconnect structure 390. The metal layer 380, liner 370, dielectric layer 360, and masking layer 310 are etched until reaching the porous dielectric layer 308 resulting in the interconnect structure 390. The masking layer 310 having a higher dielectric constant in comparison to the porous dielectric layer 308 may be completely removed in order to minimize the dielectric constant of the interconnect structure 390. In some embodiments, the planarization process stops etching upon reaching the masking layer 310 thus leaving a portion of the masking layer 310. The at least one via 314 and at least one trench 350 have been filled with the metal layer 380 (e.g., Cu plating, AlCu deposition).

FIGS. 2A and 2B illustrate the interconnect structures 200 and 290 having the restoring dielectric layer 260 deposited prior to the opening of the barrier layer 206 while FIGS. 3A and 3B illustrate the interconnect structures 300 and 390 having the restoring dielectric layer 360 deposited after the opening of the barrier layer 306. In another embodiment, the restoring dielectric layer is deposited prior to and after the opening of the barrier layer.

As previously discussed, feature critical dimension (CD) is critical for device performance. As the technology advances towards 45 nanometers (nm) and beyond, feature CD control, particularly to print the features with a small CD, becomes a major concern because the existing lithographic tools are approaching the tool limits and it becomes extremely expensive for more advanced tools.

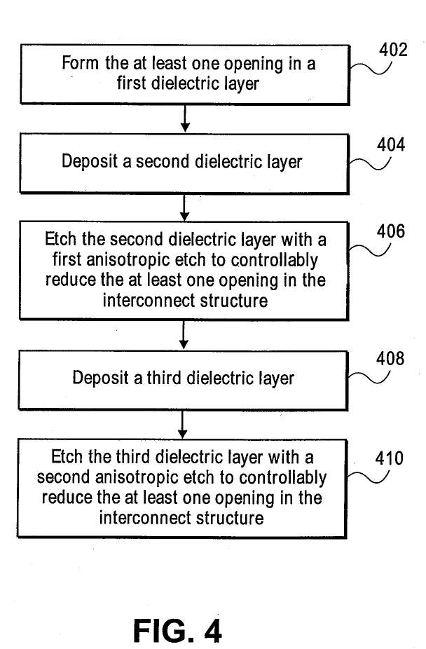

FIG. 4 illustrates one embodiment of a method for reducing a critical dimension of a interconnect structure by integrating a low-k dielectric layer into the interconnect structure. The method of controllably reducing a CD of at least one opening in the interconnect structure includes forming the at least one opening (e.g., via, trench) in a first dielectric layer at block 402. In one embodiment, forming the at least one opening in the first dielectric layer occurs by etching the first dielectric layer using a masking layer and then stripping the masking layer. The method further includes depositing a second dielectric layer to controllably reduce a CD of the at least one opening in the interconnect structure at block 404.

For some embodiments, the deposition of the second dielectric layer occurs with a deposition operation (e.g., chemical vapor deposition, physical chemical vapor deposition, plasma enhanced chemical vapor deposition, or any deposition chamber capable of depositing a low-k film) that includes an organosilicate precursor (e.g., OMCTS, TMCTS, TMS, TEOS, and DEMS) that has a composition of SiₓC_{y}O_{z}Hₘ with x=1-5, y=1-15, z=0-10, and m=3-45. The RF power may be less than or equal to 75 W with a precursor/Helium ratio greater than or equal to 1:4. A spacing between electrodes (e.g., heater and faceplate) is greater than or equal to 200 mils. The pressure during the deposition is greater than or equal to 1.8 torr with a chamber temperature between 0 and 500° C.

The deposition is self-limiting to form a thin uniform conformal Carbon doped oxide layer. Continuous growth can be enabled with a Carbon removal step using an O₂, CO₂, or N₂O plasma diluted in N₂, Argon or Helium. A final film thickness can be achieved by using a cyclic deposition. The second dielectric layer has a thickness less than 20 nanometers.

The method further includes etching the second dielectric layer with a first anisotropic etch to controllably reduce a CD of the at least one opening in the interconnect structure at block 406. The first anisotropic etch etches at a faster rate on horizontal surfaces compared to vertical surfaces.

In one embodiment, the anisotropic etch includes the following process parameters:

6-12 sccm C₄F₈; 100-200 sccm N₂; 100-500 sccm Argon; 30 mT; and 1000 watt with a RF frequency of 2 or 13 MHz in a plasma etch chamber, like Applied Materials' Enabler. Process parameters of the anisotropic etch can be altered to change the etch rate between the horizontal and vertical surfaces and also the shape of the portion of the dielectric layer that has not been removed by the anisotropic etch.

The method further includes depositing a third dielectric layer at block 408. The method further includes etching the third dielectric layer with a second anisotropic etch to controllably reduce the CD of the at least one opening in the interconnect structure at block 410. The second and third dielectric layers as deposited are low k and hydrophobic in order to not adsorb moisture during subsequent processing resulting in a reliable process control.

In one embodiment, the deposition of the second and/or third dielectric layer occurs prior to forming an opening in a barrier layer at block 104. In another embodiment, the deposition of the second and/or third dielectric occurs prior to and after forming an opening in a barrier layer at block 104. The first dielectric layer can be a porous or non-porous layer. In another embodiment, depositing and sputter etching are performed in the same chamber (e.g., chemical vapor deposition with sputtering). The deposition and sputtering can be performed in a cycle alternating between the processes in a single chamber such as Applied Materials' Producer PECVD Chambers in contrast to prior approaches that requires two separate process tools for the deposition and sputtering operations. Performing the deposition and sputtering in a single chamber can result in an increase in throughout and yield and a decrease in defects in the dielectric layers.

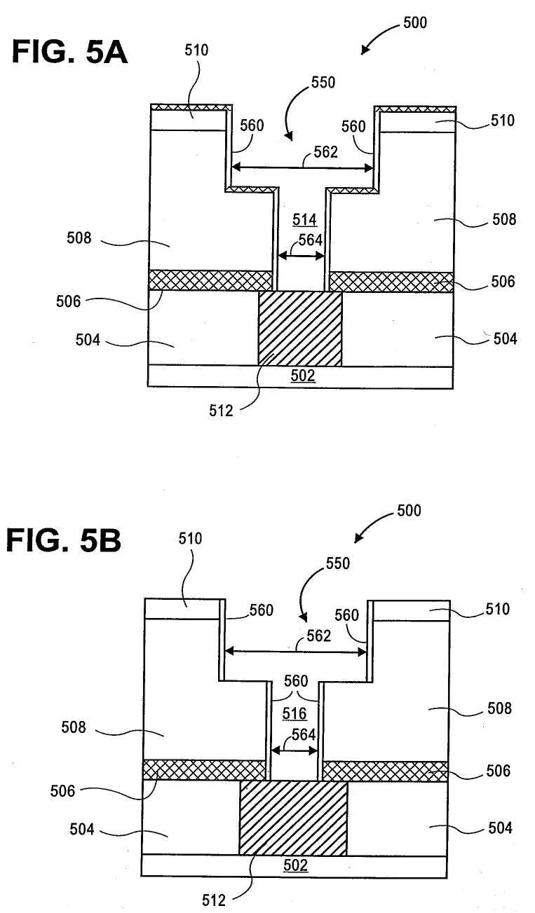

FIG. 5A illustrates a cross-sectional view of a interconnect structure in accordance with one embodiment. The interconnect structure 500 includes a substrate 502, a dielectric layer 504, a metal layer 512, a barrier layer 506, a dielectric layer 508, and a masking layer 510 (e.g., Silicon Nitride). In one embodiment, the interconnect structure 500 is a dual-damascene structure having at least one via 514 and at least one trench 550 formed from conventional semiconductor deposition, lithography, etch, and strip operations. In another embodiment, the interconnect structure 500 is a single damascene structure or other structure that forms an opening in a dielectric layer.

A via CD 564 and a trench CD 562 can be controllably reduced in accordance with the method described above and illustrated in FIG. 4. In one embodiment, a dielectric layer 560 is uniformly deposited on the masking layer 510 and the dielectric layer 508 after forming an opening in the barrier layer 506. The dielectric layer 560 will not form on the barrier layer 506 or metal layer 502 without having a seed layer formed initially. In one embodiment, the dielectric layer 560 has a thickness less than 20 nanometers. For example, the dielectric layer 560 may have a thickness of 10 nanometers thus reducing the via CD 564 and trench CD 562 by approximately 20 nanometers.

The dielectric layer 560 is then etched with an anisotropic etch to controllably reduce a CD of the at least one opening in the interconnect structure 500. The anisotropic etch etches at a faster rate on horizontal surfaces compared to vertical surfaces resulting in the removal of the horizontal shaded regions of the dielectric layer 560 as illustrated in FIGS. 5A and 5B. The thickness of the vertical portions of the dielectric layer 560 reduces the trench 562 and via 564 CDs. The vertical portions may have a square shape as illustrated in FIGS. 5A and 5B or have rounded or tapered corners depending on the process parameters of the anisotrophic etch.

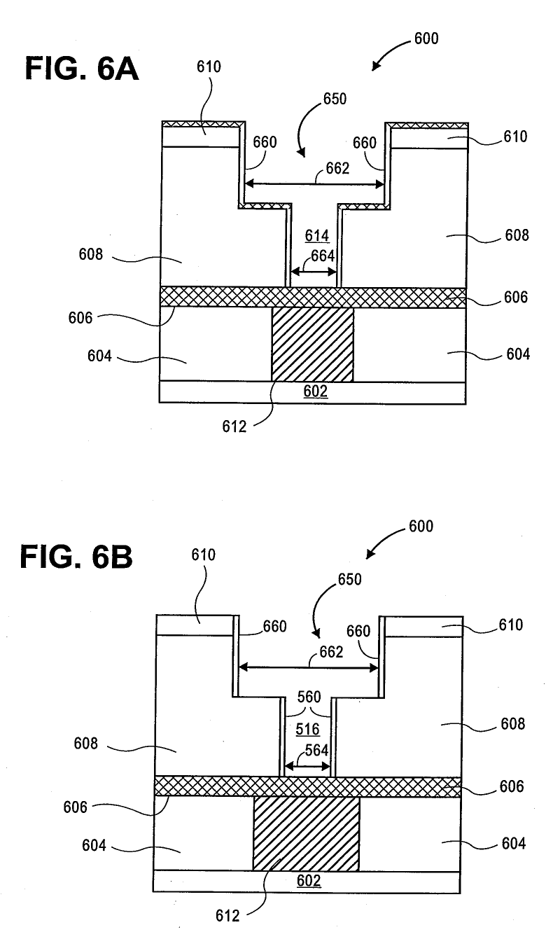

FIG. 6A illustrates a cross-sectional view of a interconnect structure in accordance with another embodiment in which a dielectric layer 660 is deposited before forming an opening in a barrier layer 606. The interconnect structure 600 includes a substrate 602, a dielectric layer 608, a metal layer 612, the barrier layer 606, the dielectric layer 660, and a masking layer 610 (e.g., Silicon Nitride). In one embodiment, the interconnect structure 600 is a dual-damascene structure having at least one via 614 and at least one trench 650 formed from conventional semiconductor deposition, lithography, etch, and strip operations.

A via CD 664 and a trench CD 662 can be controllably reduced in accordance with the method illustrated in FIG. 4. In one embodiment, a dielectric layer 660 is uniformly deposited on the masking layer 610 and the dielectric layer 608 before forming an opening in the barrier layer 606. The dielectric layer 660 is then etched with an anisotropic etch to controllably reduce the at least one opening in the interconnect structure 600. The anisotropic etch etches at a faster rate on horizontal surfaces compared to vertical surfaces resulting in the removal of the horizontal shaded regions of the dielectric layer 660 as illustrated in FIGS. 6A and 6B. The thickness of the vertical portions of the dielectric layer 660 reduces the trench 562 and via 564 CDs.

In another embodiment, the dielectric layer 660 is deposited and etched both before and after forming an opening in the barrier layer 606. The thickness of the dielectric layer 660 is optimized for a particular application. For example, if the thickness of the dielectric layer 660 is too thin, the feature CDs will merely be altered insignificantly. Alternatively, if the thickness of the dielectric layer 660 is too thick, then subsequently deposited metal layers may have adhesion or delamination issues.

For at least certain embodiments, the restoring dielectric deposition(s) and the dielectric deposition(s) that reduces the CD features have the same or similar process parameters as discussed above. In one embodiment, the restoring dielectric deposition(s) have been optimized to seal an underlying porous dielectric layer with the restoring dielectric deposition(s) having a thickness less than 30 Angstroms. In another embodiment, the thickness of the dielectric deposition(s) is selected to optimally reduce the CD features without creating integration issues. The thickness of the dielectric deposition(s) is less than 20 nanometers.

Following the reduction of critical dimension(s) (e.g., via, trench) of an interconnect structure as illustrated in FIGS. 4, 5A, 5B, 6A, and 6B, conventional semiconductor processing includes performing a clean operation on the interconnect structure prior to metallization. This metallization may include depositing a liner layer prior to depositing or plating the metal layer on the interconnect structure. In one embodiment, a top portion of the metal layer, liner layer, masking layer, and thin dielectric layers are etched with a chemical-mechanical planarization or chemical-mechanical polishing (CMP) process until reaching the porous dielectric layer (e.g., 508, 608). In another embodiment, other conventional semiconductor processing occurs in order to etch the metal layer such as a blanket unmasked plasma etch or a masked plasma etch or a combination of conventional semiconductor processing.

In the following description, numerous details are set forth. It will be apparent, however, to one skilled in the art, that the present invention may be practiced without these specific details. In some instances, well-known structures and devices are shown in block diagram form, rather than in detail, in order to avoid obscuring the present invention.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method of restoring a porous dielectric layer, comprising:
forming an opening in a porous dielectric layer; and
depositing a restoring dielectric layer to seal a surface layer of pores of the porous dielectric layer, wherein the restoring dielectric layer is hydrophobic to prevent the porous dielectric layer from adsorbing moisture and consequently increasing a dielectric constant of the porous dielectric layer.

2. The method of claim 1, wherein the restoring dielectric layer is formed from an organosilicate precursor that has a composition of SiₓC_{y}O_{z}Hₘ with x=1-5, y=1-15, z=0-10, and m=3-45.

3. The method of claim 2, wherein a ratio of the organosilicate precursor to Helium is greater than or equal to 1:4.

4. The method of claim 1, wherein depositing the restoring dielectric layer occurs before or after forming an opening in a barrier layer.

5. The method of claim 1, wherein depositing the restoring dielectric layer occurs before and after forming an opening in a barrier layer.

6. The method of claim 1, wherein the porous and restoring dielectric layers each have low dielectric constants.

7. The method of claim 1, wherein the restoring dielectric layer has a thickness with a range of 5 to 30 Angstroms.

8. An interconnect structure, comprising:
a porous dielectric layer disposed on a barrier layer with at least one opening in the porous dielectric layer overlying at least one opening in the barrier layer; and
a restoring dielectric layer disposed to seal a surface layer of pores of the porous dielectric layer, wherein the restoring dielectric is hydrophobic to prevent the porous dielectric layer from adsorbing moisture and consequently increasing a dielectric constant of the porous dielectric layer.

9. The interconnect structure of claim 8, wherein the restoring dielectric layer is formed from an organosilicate precursor that has a composition of SiₓC_{y}O_{z}Hₘ with x=1-5, y=1-15, z=0-10, and m=3-45.

10. The interconnect structure of claim 8, wherein the restoring dielectric layer is deposited before or after forming an opening in a barrier layer.

11. The interconnect structure of claim 8, wherein depositing the restoring dielectric layer occurs before and after forming an opening in a barrier layer.

12. A method of controllably reducing at least one opening in a interconnect structure, comprising:
forming the at least one opening in a first dielectric layer;
depositing a second dielectric layer; and
etching the second dielectric layer with a first anisotropic etch to controllably reduce a critical dimension (CD) of the at least one opening in the interconnect structure.

13. The method of claim 12, further comprising:
depositing a third dielectric layer; and
etching the third dielectric layer with a second anisotropic etch, wherein depositing and etching the third dielectric layer further controllably reduces the CD of at least one opening in the interconnect structure.

14. The method of claim 12, wherein the first and second anisotropic etches do not result in striation or line edge roughness.

15. The method of claim 12, wherein the first and second anisotropic etches include the following process gases: 6-12 sccm C₄F₈; 100-200 sccm N₂; and 100-500 sccm Argon.

16. The method of claim 12, wherein depositing the second dielectric layer occurs before or after forming an opening in a barrier layer.

17. The method of claim 12, wherein depositing the second dielectric layer occurs before and after forming an opening in a barrier layer.

18. The method of claim 12, wherein the first and second dielectric layers have low dielectric constants.

19. The method of claim 12, wherein the second dielectric layer has a thickness less than 20 nanometers.

20. The method of claim 12, wherein the at least one opening comprises at least one via.

21. The method of claim 12, wherein the at least one opening comprises at least one trench.

22. The method of claim 12, wherein the depositing and etching occurs in the same process chamber.

23. The method of claim 12, wherein the depositing and etching occurs in the same process chamber in an alternating cycle.
